(19) United States
(12) Patent Application Publication
(10) Pub. No.: US 2004/0012065 A1
(43) Pub. Date: Jan. 22, 2004

(54) Semiconductor integrated circuit device

(75) Inventor: Masahiro Shiina, Ora-gun (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-City (JP)

(21) Appl. No.: 10/446,141

(22) Filed: May 28, 2003

(30) Foreign Application Priority Data
May 29, 2002 (JP) 2002-155312

(51) Int. Cl. H01L 31/00

(52) U.S. Cl. 257/459

(57) ABSTRACT

Unnecessary crossing of interconnections are eliminated to reduce impedance of LSI wiring in a semiconductor integrated circuit device. The semiconductor integrated circuit device includes a circuit block having many elements such as resistances, transistors and capacitors. Pad electrically connected with the circuit blocks and protection circuits electrically connected with the pads are aligned along a periphery of the circuit block. Impedance of the wiring in the LSI is reduced by disposing a top layer metal providing a power supply voltage Vcc along outer sides of the aligned pads and protection circuits, and by disposing a bottom layer metal providing ground voltage as wide as possible over the entire space between the circuit block and the aligned pads and protection circuits.

### BACKGROUND OF THE INVENTION

1. Field of the Invention

This invention relates to a protection circuit of a semiconductor integrated circuit device, specifically to a protection circuit with reduced wiring.

2. Description of the Related Art

A semiconductor integrated circuit device has a possibility of breakdown when an excessive external voltage is applied to its input pin. Various kinds of input protection circuits are incorporated in semiconductor integrated circuit devices to prevent this breakdown.

For example, a polysilicon gate MOS integrated circuit is provided with a protection circuit 80 as shown in FIG. 6. The protection circuit 80 includes two diodes D3 and D4 connected in series. A cathode of the protection diode D3 is connected to Vcc (power supply voltage), while an anode of the protection diode D4 is connected to GND (ground voltage or reference voltage). An input terminal 81 is connected to a connecting node 83 between the two protection diodes D3 and D4 and further connected to an internal circuit through a terminal 82.

An excessive external voltage due to an electrostatic discharge, or the like, is applied to the input terminal 81 of the protection circuit 80. When a voltage higher than Vcc is applied, the protection diode D3 conducts to clamp the voltage at the connecting node 83, and keeps the internal circuit beyond the terminal 82 from the high voltage. Similarly, when a negative high voltage lower than GND is applied, the protection diode D4 conducts to clamp the voltage at the connecting node 83, and keeps the internal circuit beyond the terminal 82 from the negative high voltage.

FIG. 7 is a plan view of a conventional semiconductor integrated circuit device, that is, an LSI 100 with the protection circuit 80. The LSI 100 includes three circuit blocks 101A-101C, 16 pads 102A-102P and 16 protection circuits 104A-104P. The circuit block denotes a circuit containing many elements such as resistances, transistors and capacitors.

Each of the pads 102A-102P is connected with each of the circuit blocks 101A-101C through an interconnection 103. Each of the protection circuits 104A-104P is connected with each of the pads 102A-102P through an interconnection 105, respectively.

Each of the protection circuits 104A-104P contains the protection circuit 80 shown in FIG. 6 and requires two interconnections (not shown) to electrically connect with a Vcc wiring and a GND wiring formed in the LSI 100. An area each of the protection circuits 104A-104P takes up is about ⅓ to ½ of that of each of the pads 102A-102P.

In the layout design of the semiconductor integrated circuit device shown in FIG. 7, placement of the elements is usually determined through the following procedures.

First, three circuit blocks 101A-101C are disposed around a center of the LSI 100. Positional relationship among positions of the three circuit blocks is determined considering die size and functionality. In FIG. 7, the circuit blocks 101A and 101B having the same area are placed parallel to the largest circuit block 101C.

Second, the pads 102A-102P are disposed at regular intervals around the three circuit blocks 101A-101C.

Third, the protection circuits 104A-104P are disposed in the LSI 100. Since each of the protection circuits 104A-104P takes up a small area than each of the pads 102A-102P, each of the protection circuits 104A-104P is placed in an empty space, or so-called a dead space, between the circuit blocks 111A-111C and the pads 102A-102P.

Then, interconnections 103 electrically connecting the circuit blocks 101A-101C and the pads 102A-102P, and interconnections 105 electrically connecting the pads 102A-102P and the protection circuits 104A-104P are disposed. In addition, the Vcc wiring and the GND wiring for the protection circuits 104A-104P are disposed.

However, there are the following disadvantages when the elements of the conventional semiconductor integrated circuit device shown in FIG. 7 are disposed.

First, there are crossings between the interconnections 103 and the interconnections 105, since the protection circuits 104A-104P are disposed utilizing the so-called dead space in the LSI 100. Looking at the pad 102A and the protection circuit 104A in the lower right corner of the LSI 100 in FIG. 7, for example, the interconnection 103 and the interconnection 105 intersect each other.

The crossing of the interconnection 103 and the interconnection 105 may cause a trouble such as a short circuit an interference in signal lines. In addition, the interconnections 103 and 105 and the Vcc and GND wiring, with which the protection circuits 104A-104P are connected, are intertwined with each other complicatedly. This may cause an unexpected adverse effects in a designed layout, requiring a thicker interlayer isolation film or more via holes.

Second, in the semiconductor integrated circuit device of recent years which has multi layer structure and thus requires complicated manufacturing processes, larger number of interconnections increases the impedance of the interconnections, resulting in deterioration in characteristics of the LSI 100.

### SUMMARY OF THE INVENTION

The invention provides a semiconductor integrated circuit device that includes a plurality of circuit blocks, a plurality of pads and a plurality of protection circuits. Each of the pads is electrically connected to a corresponding one of the circuit blocks. Each of the protection circuits is electrically connected to a corresponding one of the pads. The device also includes a first wiring configured to provide the protection circuits with a first electric potential, and a second wiring configured to provide the protection circuits with a second electric potential different from the first electric potential. Each of the pads and its corresponding protection circuit are disposed adjacent each other, and the pads and the corresponding protection circuits are aligned along a periphery of a corresponding one of the circuit blocks. The first wiring is disposed on a side of the aligned pads and protection circuits opposite from the circuit blocks, and the second wiring is disposed to cover substantially the entire area between the circuit blocks and the aligned pads and protection circuits.

The invention also provides a semiconductor integrated circuit device that includes a plurality of circuit blocks, a plurality of pads and a plurality of protection circuits. Each of the pads is electrically connected to a corresponding one of the circuit blocks. Each of the protection circuits is integrated with a corresponding one of the pads as an integrated device element. An internal electrical connection is provided within the integrated device element between the pad and the corresponding protection circuit. The device also includes a first wiring configured to provide the protection circuits with a first electric potential, and a second wiring configured to provide the protection circuits with a second electric potential different from the first electric potential. The integrated device elements are aligned along a periphery of a corresponding one of the circuit blocks. The first wiring is disposed on a side of the aligned integrated device elements opposite from the circuit blocks, and the second metal wiring is disposed to cover substantially the entire area between the circuit blocks and the aligned integrated device elements.

### BRIEF DESCRIPTION OF THE DRAWINGS

FIG. 1 is a plan view of a semiconductor integrated circuit device according to an embodiment of this invention.

FIG. 2 is an oblique perspective view of the device of FIG. 1.

FIG. 3 is a partially expanded plan view of FIG. 1 to show the details of an integrated device element including a pad and a protection circuit.

FIG. 4 is a cross-sectional view of the portion of the device of FIG. 3 cut along line X1-X2 of FIG. 3.

FIG. 5 is a cross-sectional view of the portion of the device of FIG. 3 cut along line Y1-Y2 of FIG. 3.

FIG. 6 is a circuit diagram of a conventional protection circuit.

FIG. 7 is a plan view of a conventional semiconductor integrated circuit device.

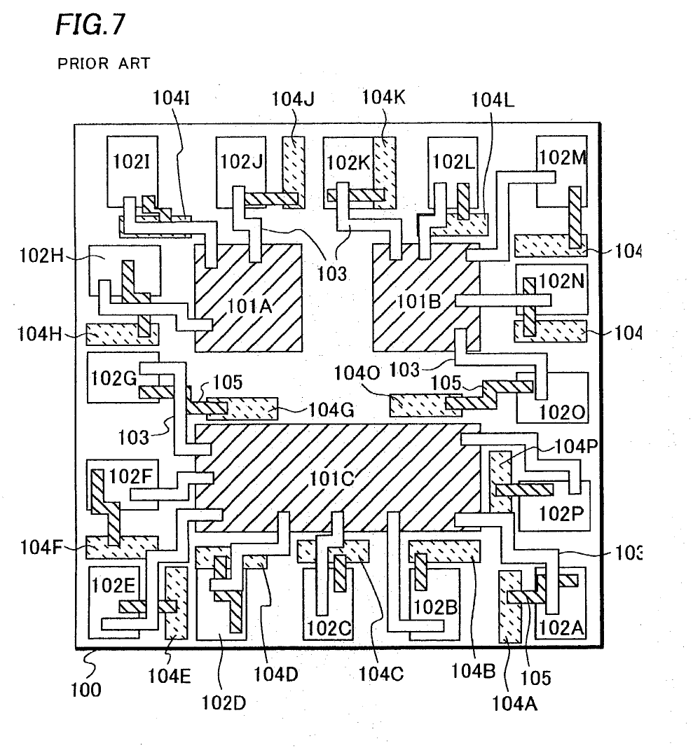

### DETAILED DESCRIPTION OF THE INVENTION

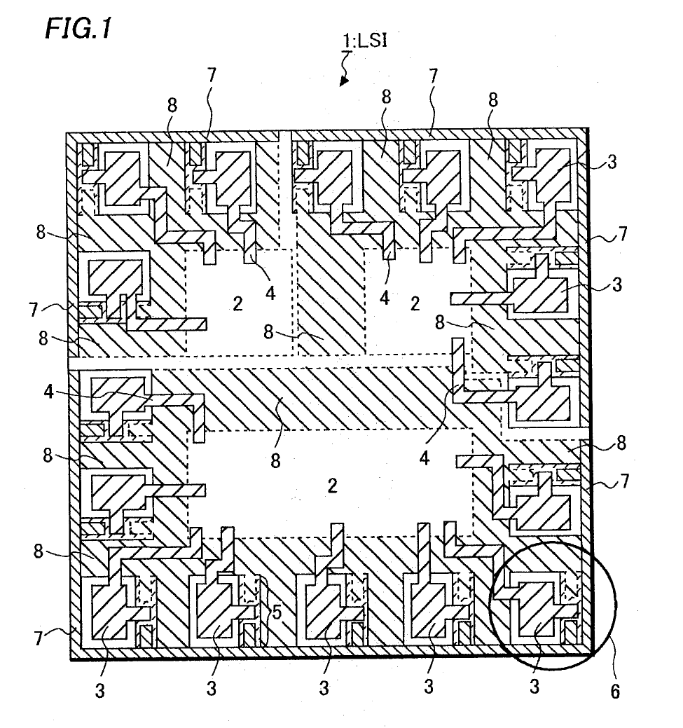

An embodiment of this invention is explained referring to FIGS. 1-5.

FIG. 1 is a plan view of a semiconductor integrated circuit device (hereafter referred to as an LSI) 1 according to an embodiment of this invention. Pads 3 are formed around circuit blocks 2, and the circuit blocks 2 and the pads 3 are electrically connected through interconnections 4. The circuit block 2 denotes a circuit containing many elements such as resistances, transistors and capacitors.

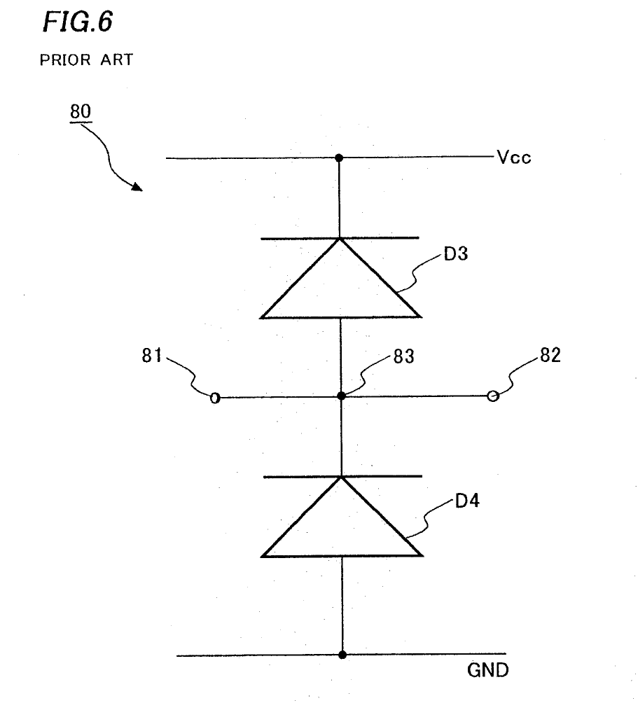

The interconnection 4 is a metal interconnection connecting the circuit block 2 and the pad 3. A protection circuit 5 disposed adjacent to the pad 3 has two diodes connected in series, the equivalent circuit of which is the same as shown in FIG. 6.

In this embodiment, there are three circuit blocks 2 disposed around the center of the LSI 1 and 16 pads. Nevertheless, the number of the circuit blocks 2 and the number of the pads 3 are not limited to these numbers.

Each of the protection circuits 5 is disposed adjacent to one of the pads 3 to form an integrated device element (hereafter referred to as a cell) 6. These cells are aligned in a predetermined pattern.

The semiconductor integrated circuit device shown in FIG. 1 has a multi layer structure and includes a plurality of metal wiring layers. A top layer metal 7 and a bottom layer metal 8 are placed both inside and outside of the aligned cells. A power supply voltage Vcc is provided to the top layer metal 7, while a ground voltage GND is provided to the bottom layer metal 8. The top layer metal 7 forms a Vcc wiring and the bottom layer metal 8 forms a GND wiring. And the Vcc wiring and the GND wiring provide the circuit blocks 2 and the protection circuits 5 with Vcc and GND, respectively.

The bottom layer metal 8 is formed wide over the whole space between the circuit blocks 2 and the cells 6 The bottom layer metal 8 is placed close to the circuit blocks 2 and the cells 6, as long as short circuit is prevented. In addition, the bottom layer metal 8 may be formed over the entire space between the neighboring cells 6. Similarly, the bottom layer metal 8 may be formed as the GND (ground) wiring over the entire space between the neighboring circuit blocks 2.

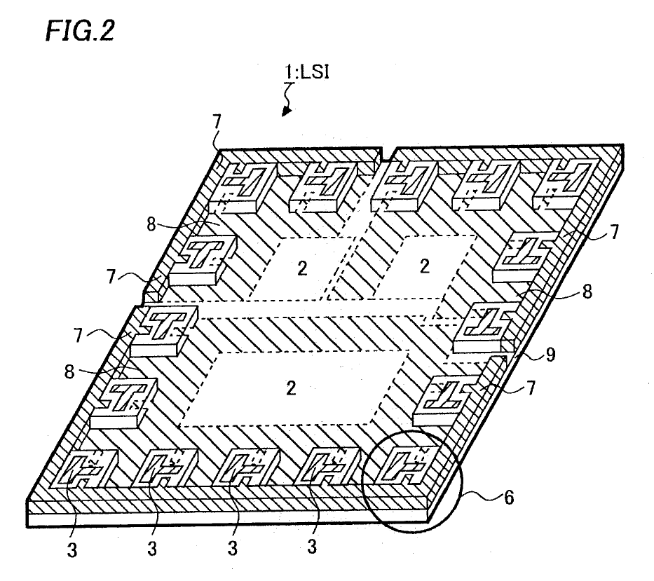

FIG. 2 is a bird's eye view of the LSI 1 looked from above obliquely. The interconnections 4 shown in FIG. 1 are omitted for the sake of simplicity. An interlayer insulation film 9 is formed on the LSI 1. Each of the cells 6 is the integrated structure having the pad 3 and the protection circuit 5, and the cells are aligned along each side of the LSI 1 with a certain regularity.

The top layer metal 7 is formed by sputtering aluminum and extends along the outer sides of the aligned cells 6 keeping a certain width and connecting with the diodes D1 on the outer sides of the protection circuits 5.

Forming the top metal layer 7 along the outer sides of the cells 6 as described is to make the width of the top metal layer 7 wide and to reduce impedance of the Vcc wiring made of the top metal layer 7.

The bottom layer metal 8 is formed by sputtering aluminum as well, and is formed wide over the whole space between the circuit blocks 2 and the cells 6, as described with reference to FIG. 1. The bottom layer metal 8 is connected with the diode 2 disposed inner side of the protection circuits 5.

Forming the bottom metal layer 8 wide and along the inner sides of the aligned cells 6 as described above is to reduce the impedance of the GND wiring connected with the bottom metal layer 8.

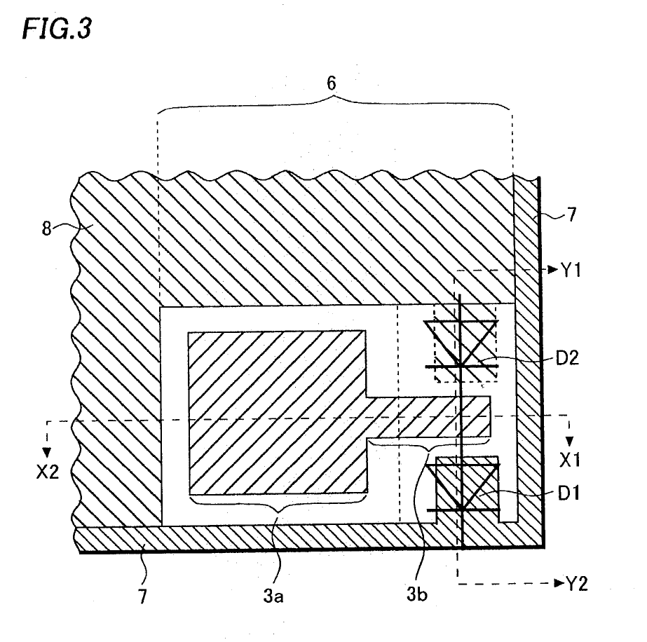

FIG. 3 is an enlarged plan view of the cell 6. The top metal layer 7 extends along the outer sides of the cells 6 and along the periphery of the LSI 1, and extends over the surface of the diode D1 in the protection circuit 5.

The bottom layer metal 8 is a wide metal wiring formed inner side of the aligned cells 6. The bottom metal layer 8 is formed under the interlayer insulation film 9 and on an oxide film 24.

The cell 6 includes the pad 3 and the protection circuit 5, which are integrated together. The pad 3 has a larger rectangular-shaped bonding pad 3a and a smaller rectangular-shaped extension 3b formed continuously.

A bonding wire (not shown) is formed on the bonding pad 3a which is electrically connected with the circuit block 2 through the interconnection 4 as shown in FIG. 1. The extension 3b is directly connected with the protection circuit 5 formed below. The protection circuit 5 has two diodes D1 and D2 connected in series. The bottom layer metal 8 is a part of a wiring layer that includes a bottom layer wiring of the diode D2.

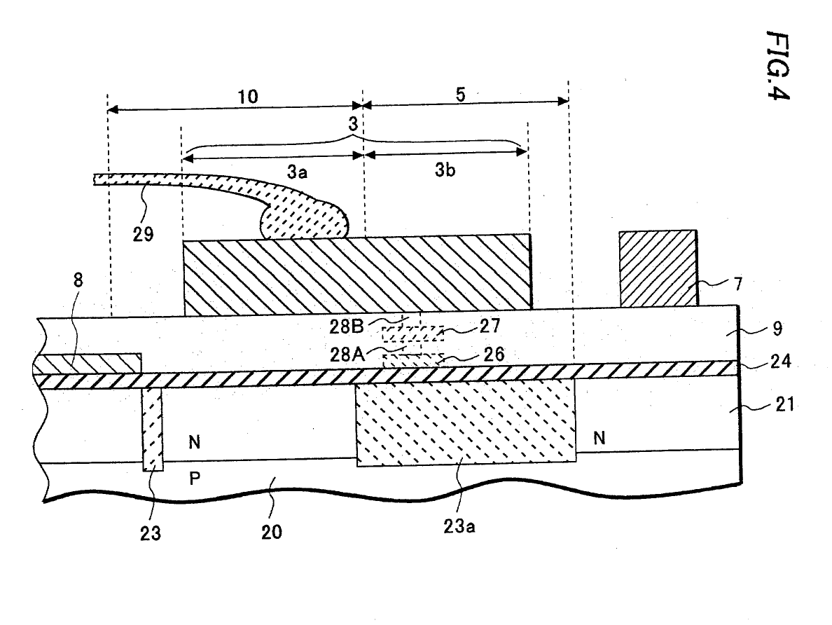

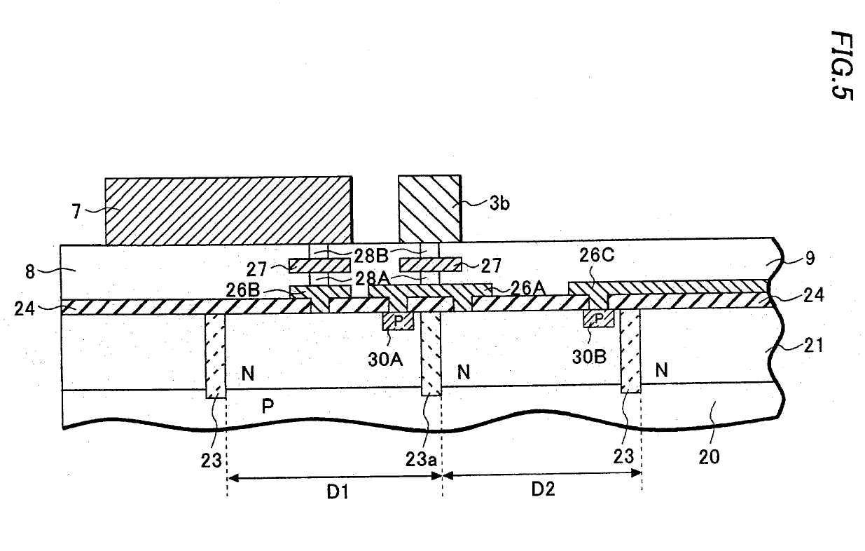

FIG. 4 is a cross-sectional view of a section X1-X2 shown in FIG. 3, and FIG. 5 is a cross-sectional view of a section Y1-Y2 shown in FIG. 3. FIG. 4 and FIG. 5 are magnified to schematically depict the features of the cross-sectional structure.

As shown in FIG. 4, an N-type semiconductor layer 21 is formed on a P-type semiconductor substrate 20. The semiconductor layer 21 is electrically divided with isolation layers 23 and 23a. The isolation layer 23a separates the two diodes D1 and D2 in the protection circuit 5 from each other. That is, the diode D1 is placed in front of the isolation layer 23a while the diode D2 is placed behind the isolation layer 23a with respect to this sectional plane. An oxide film 24 is a silicon dioxide film formed on the surface of the semiconductor layer 21 by thermal oxidation.

An interlayer insulation film 9 is formed on the oxide film 24. A plurality of metal layers (for example, bottom layer metals 8 and 26 and an intermediate layer metal 27 in the figure) and a plurality of contact holes, for example 28A and 28B, electrically connecting the metal layers are formed in the interlayer insulation film 9.

Next, each of the metal layers and others in the interlayer insulation film 9 is explained. The bottom layer metal 26 is formed at a desired position on the surface of the oxide film 24 and makes contact with the connection node between the diodes D1 and D2 in the protection circuit 5. The bottom layer metal 26 of the protection circuit is a part of a wiring layer that includes the bottom layer metal 8.

The bottom layer metal 26 is connected with the pad 3 through the contact hole 28A, the intermediate layer metal 27 and the contact hole 28B. There are two metal layers (the bottom layer metal 26 and the intermediate layer metal 27) in the interlayer insulation film 9 in this embodiment. However, the number of metal layers may be different. The bottom layer metal 8 shown in FIG. 4 extends to the isolation layer 23, i.e., the boundary of the cell 6.

The pad 3 is formed on a desired position on the surface of the interlayer insulation film 9. A bonding wire 29 is attached to the bonding pad 3a. The region below the bonding pad 3a can accommodate structures such as a deep trench without difficulties.

The top layer metal 7 and the pad 3 are formed in the same sputtering process. In this case, the pad 3 has the same film thickness as the top metal layer 7. Or the top layer metal 7 and the pad 3 may be formed in separate processes and have different film thickness.

As shown in FIG. 5, the semiconductor layer 21 formed on the semiconductor substrate 20 is electrically divided with the isolation layers 23 and 23a. The isolation layer 23a separates the diode D1 and the diode D2. The oxide film 24 covers the surface of the semiconductor layer 21.

The diodes D1 and D2 have P-type layers 30A and 30B formed by diffusion from the surface of the semiconductor layer 21. The P-type layer 30A is an anode of the diode D1, and the P-type layer 30B is an anode of the diode D2.

The bottom layer metals 26A, 26B and 26C of the protection circuit are formed on the oxide film 24 as a part of the same wiring layer as bottom metal layer 8. Each of the bottom layer metals of the protection circuit makes contact with the N-type semiconductor layer 21 or the P-type layers 30A and 30B.

The bottom layer metal 26A connects the P-type layer 30A of the diode D1 and the N-type layer of the diode D2. The bottom layer metal 26A is connected through the contact hole 28A to the intermediate layer metal 27 which is connected to the extension 3b through another contact hole 28B.

The bottom layer metal 26B makes contact with the N-type layer of the diode D1 and connected with the top layer metal 7 formed on the interlayer insulation film 9 through the contact hole 28A, intermediate layer metal 27 and the contact hole 28B.

The bottom layer metal 26C makes contact with the P-type layer 30B of the diode D2, and extends beyond the diode D2 to reach the vicinity of a neighboring cell 6. The bottom layer 26C is at the GND voltage. The bottom layer metal 26B is provided with the power supply voltage Vcc through the top layer metal 7. Accordingly, each of the bottom layer metals 26A, 26B, 26C is electrically isolated from each other. In addition, each of the circuit blocks is provided with the power supply voltage and the GND voltage.

The thickness of the top layer metal 7 and the thickness of the pad 3 are not necessarily the same. For example, when especially low impedance of the Vcc wiring is preferred, the thickness of the top layer metal 7 may be made extremely thick (twice of that of the pad 3, for example).

As described above, this invention has following effects.

Interconnections between the pads 3 and the protection circuits 5 are no longer needed, since the pads 3 and the corresponding protection circuits 5 are integrated into the cells 6. In this configuration, each of the cells 6 is connected to the corresponding circuit block 2 with a single interconnection 4, leading to elimination of unnecessary crossing of the interconnections, and prevention of adverse effects such as short circuit. And it is possible to omit process steps to form metal wirings, which are necessary to provide the protection circuits with the power supply voltage Vcc and the ground voltage GND in the conventional art.

Once the cell 6 which integrates the pad 3 and the protection circuit 5 is designed, it can used repeatedly in the layout design as the same integrated device element. On the contrary, the conventional art requires time and effort to locate each of the protection circuits 104A-104P in the dead space in the LSI 100. With the integrated cell 6 of this embodiment, such time and effort in the layout design can be saved. Furthermore, signals are processed reliably because of the absence of interconnection of the signal lines.

In addition, the impedance of the GND wiring can be set low by forming the bottom layer metal 8 along inner side of each of the cells 6 as wide as the design allows.

The impedance of the Vcc wiring can be reduced by forming the top layer metal 7 extending along the outer side of the cells 6 and increasing the width of the top layer metal 7. The impedance of the top layer metal 7 can be further reduced by making the thickness of the top layer metal 7 as thick as the design allows.

It is noted that all of the diodes D2 connected to the bottom layer metal 26C are placed inner side of the LSI, and that all of the diodes D1 connected to the bottom metal layer 26B are placed outer side of the LSI.

Although the power supply voltage Vcc is connected to the top layer metal 7 disposed outer sides of the cells 6, and the ground voltage GND is provided to the bottom layer metal 7 disposed inner sides of the cells 6 in this embodiment, it is also possible that the power supply voltage Vcc is connected to the bottom layer metal 8 and the ground voltage GND is connected to the top layer metal 7. In this case, the orientation of each of the diodes in the protection circuits is reversed.

Although the protection circuits 5 relies on diodes in this embodiments, the protection circuits may includes MOS transistors, bipolar transistors, PIN diodes or clamp circuits.

What is claimed is:

1. A semiconductor integrated circuit device comprising:
a plurality of circuit blocks;
a plurality of pads, each of the pads being electrically connected to a corresponding one of the circuit blocks;
a plurality of protection circuits, each of the protection circuits being electrically connected to a corresponding one of the pads;
a first wiring configured to provide the protection circuits with a first electric potential; and
a second wiring configured to provide the protection circuits with a second electric potential different from the first electric potential, wherein
each of the pads and the corresponding protection circuit thereof are disposed adjacent each other, and the pads and the corresponding protection circuits are aligned along a periphery of a corresponding one of the circuit blocks, and
the first wiring is disposed on a side of the aligned pads and protection circuits opposite from the circuit blocks, and the second wiring is disposed to cover substantially the entire area between the circuit blocks and the aligned pads and protection circuits.

2. The semiconductor integrated circuit device of the claim 1, wherein the second wiring is disposed between the circuit blocks

3. The semiconductor integrated circuit device of the claim 1, wherein the second wiring is disposed between a first pair of one of the pads and the corresponding protection circuit thereof and a second pair of another one of the pads and the corresponding protection circuit thereof.

4. The semiconductor integrated circuit device of the claim 1, wherein the first wiring is a part of a first wiring layer, and the second wiring is a part of a second wiring layer different from the first wiring layer.

5. The semiconductor integrated circuit device of the claim 1, wherein each of the protection circuits comprises a first diode and a second diode connected in series.

6. The semiconductor integrated circuit device of the claim 5, wherein a cathode of the first diode is configured to receive the first electric potential or the second electric potential, and an anode of the second diode is configured to receive the first electric potential or the second electric potential that is not received by the cathode of the first diode.

7. The semiconductor integrated circuit device of the claim 6, wherein the first electric potential is a power voltage supplied to the protection circuit, and the second electric potential is a ground voltage supplied to the protection circuit.

8. The semiconductor integrated circuit device of the claim 7, wherein the first wiring is a part of a wiring layer that is above a wiring layer of the second wiring, and the cathode of the first diode is configured to receive the power voltage and the anode of the second diode is configured to receive the ground voltage.

9. A semiconductor integrated circuit device comprising:
a plurality of circuit blocks;
a plurality of pads, each of the pads being electrically connected to a corresponding one of the circuit blocks;
a plurality of protection circuits, each of the protection circuits being integrated with a corresponding one of the pads as an integrated device element, an internal electrical connection being provided within the integrated device element between the pad and the corresponding protection circuit;
a first wiring configured to provide the protection circuits with a first electric potential; and
a second wiring configured to provide the protection circuits with a second electric potential different from the first electric potential, wherein
the integrated device elements are aligned along a periphery of a corresponding one of the circuit blocks, and
the first wiring is disposed on a side of the aligned integrated device elements opposite from the circuit blocks, and the second metal wiring is disposed to cover substantially the entire area between the circuit blocks and the aligned integrated device elements.

10. The semiconductor integrated circuit device of the claim 9, wherein the second wiring is disposed between the circuit blocks

11. The semiconductor integrated circuit device of the claim 9, wherein the second wiring is disposed between the integrated device elements.

12. The semiconductor integrated circuit device of the claim 9, wherein the first wiring is a part of a first wiring layer, and the second wiring is a part of a second wiring layer different from the first wiring layer.

13. The semiconductor integrated circuit device of the claim 9, wherein each of the protection circuits comprises a first diode and a second diode connected in series.

14. The semiconductor integrated circuit device of the claim 13, wherein a cathode of the first diode is configured to receive the first electric potential or the second electric potential, and an anode of the second diode is configured to receive the first electric potential or the second electric potential that is not received by the cathode of the first diode.

15. The semiconductor integrated circuit device of the claim 14, wherein the first electric potential is a power voltage supplied to the protection circuit, and the second electric potential is a ground voltage supplied to the protection circuit.

16. The semiconductor integrated circuit device of the claim 15, wherein the first wiring is a part of a wiring layer that is above a wiring layer of the second wiring, and the cathode of the first diode is configured to receive the power voltage and the anode of the second diode is configured to receive the ground voltage.
